(19) United States
(12) Patent Application Publication
(10) Pub. No.: US 2021/0343582 A1
(43) Pub. Date: Nov. 4, 2021

(54) METHODS OF MANUFACTURING A TRANSISTOR DEVICE

(71) Applicant: Search For The Next, LTD., Nottingham (GB)

(72) Inventor: David SUMMERLAND, Nottingham Nottinghamshire (US)

(21) Appl. No.: 17/284,524

(22) PCT Filed: Oct. 14, 2019
(86) PCT No.: PCT/GB2019/052924

§ 371 Date: Apr. 12, 2021

(30) Foreign Application Priority Data
Oct. 12, 2018 (GB) 1816688.4
Oct. 22, 2018 (GB) 1817199.1
May 29, 2019 (GB) PCT/GB2019/051465
Sep. 20, 2019 (GB) 1913638.1

(51) Int. Cl. H01L 21/762; H01L 27/082; H01L 21/8224; H01L 21/8222; H01L 29/66; H01L 29/735

(52) U.S. Cl. CPC H01L 21/76224; H01L 27/0821; H01L 21/8224; H01L 27/0825; H01L 29/6625; H01L 29/735; H01L 21/8222

(57) ABSTRACT

A method of subdividing a semiconductor wafer is described with trenches in order to provide separate, electrically isolated regions that can be used to hold components that operate at different voltages. There is also described a masking and etching process of forming collector and emitter regions of a lateral bipolar transistor, from a layer of polysilicon deposited on a patterned later of silicon dioxide.

### CROSS-REFERENCE TO RELATED APPLICATIONS

This application claims priority from and is related to the following prior application Patent Cooperation Treaty Patent PCT/GB2019/052924, filed on Oct. 14, 2019, which claims priority from and is related to Great British Patent Application No. 1816688.4, filed on Oct. 12, 2018, which claims priority and is related to Great British Patent Application No. 1817199.1, filed Oct. 22, 2018, which claims priority from and is related to the following prior application Patent Cooperation Treaty Patent PCT/GB2019/051465, filed on May 29, 2019, which claims priority and is related to Great British Patent Application No. 1913638.1, filed Sep. 20, 2019. These prior applications, including the entirety of the written description and drawing figures, are hereby incorporated into the present application by reference.

### BACKGROUND

The present application generally relates to a transistor device and more specifically to method of manufacturing a semiconductor bipolar transistor device

With reference to FIG. 1, in PCT/GB2019/050374 (and hereby incorporated by reference) the applicant described a discrete semiconductor transistor device 1 that includes a bipolar junction transistor 2 (e.g. a power transistor) and programmable controller circuitry 4 for controlling the transistor 2. The bipolar transistor 2 and electronic components of the programmable controller circuitry 4 are all integrated on a single semiconductor chip 3. The device 1 has especial utility as a power management integrated circuit device.

The use of a ‘normally on’ transistor, namely where the transistor functions in an ON state in the absence of a signal applied to the base, is desirous for the formation of digital logic circuits as they allow for the construction of logic gates without need for complementary transistors, halving the transistor count.

It is known that a bipolar junction transistor (BJT) can be operated as a normally on transistor through a circuit configuration in which the base of the BJT is connected to ground through a resistor. When a voltage is applied across the emitter and base terminals of the BJT, the emitter being more positive, a current can flow out of the base terminal and through the resistor. This allows for current flow between the emitter and collector terminals of the transistor, in other words the transistor is ON. To turn OFF the transistor, the base of the transistor is connected to a current source able to provide sufficient current through the resistor that the current through the transistor drops sufficiently (or stops) such that current flow between the emitter and collector ceases.

The temperature coefficient of resistors are typically large. This makes it difficult to provide the aforementioned circuit with operationally stability over a wide range of temperatures. Further, the resistance value (ohms) of the resistor must be large to be sufficiently current limiting that the transistor can be switched off with the maximum current available from the current source. Resistors with values that meet this requirement are physically relatively large. For these reasons it is impracticable to use this circuit design in many integrated circuits (IC).

In PCT/GB2019/051465, herein incorporated by reference, and illustrated in FIGS. 2A and 2B, the applicant details a circuit and semiconductor layer structure that provides an integrated transistor 10 and diode 14, typically a zener diode. The diode 14, which is reversed biased and operated at a voltage below its breakdown voltage—such that conduction through the diode is a consequence of tunnelling—provides the current limiting function of a large resistor of the prior art circuit; however, the diode 14, unlike a resistor, is a relatively small electronic component and therefore makes it more feasible for use in implementing digital logic circuits, such as, for example the controller circuitry of the discrete semiconductor transistor device of FIG. 1.

Referring to FIG. 2B the lateral bipolar junction transistor is provided from a first n-type semiconductor region 100, which provides a base region of the transistor, formed in a p-type layer 101 (e.g. substrate in which multiple regions 100 may be provided and isolated from one another by the substrate to form multiple transistor zener diode circuit devices). A portion of the n-type region 100 is heavily doped to provide an n+ type region 102. The n+ region 102 is in contact with the both the p substrate 101 and a base contact B of the transistor. The n+ region 102 extends beneath the less heavily doped part of the n-type region 10. Though in an alterative arrangement the n+ region 102 may not extend beneath the n-type region 100.

A pattern of polysilicon is provided on the n-type region 100 (e.g. on the surface of the silicon wafer) to define separate p-type regions 103, 104 that provide the collector and emitter regions of the transistor. Contacts for the collector and base are provided on region 103, 104 to provide emitter and connector contacts.

The p-type regions 103, 104 are favourably manufactured by depositing undoped or lightly doped polysilicon on the wafer and then doping in situ. The conditions of the doping process favourably cause portions of the n-type region 100 immediately adjacent the polysilicon to be counter-doped so that they form part of the p-type regions 103, 104.

A further p+ region 105A, which forms one half of the zener diode, is provided by the heavily doped polysilicon layer 105A that provided the p-type regions 103, 104. The polysilicon region 105A extends laterally across a PN junction within the wafer between the n+ base region 102 of the transistor and the relatively lightly doped p-type substrate 100 (though in a variant it may extend over the p-type substrate only). Again, undoped or relatively lightly doped polysilicon may be deposited on the silicon wafer and then doped in situ to form p-type layer region 105A. Favourably the doping conditions are selected to convert a portion of the p-type substrate immediately adjacent the n+ layer 102 so as to form part of the heavily doped p+ region 105A.

### BRIEF SUMMARY

The present application describes methods that can be used in the construction of the discrete semiconductor device of FIG. 1 and structure of circuit of FIGS. 2A and 2B.

According to a first aspect of the invention there is provided a method of manufacturing a semiconductor bipolar transistor device, the semiconductor device comprising two transistors, the method comprising;

providing a semiconductor material of a first type having provided on it a first layer of a semiconductor material of a second type;

forming a trench that extends through the first layer so as to create two regions of the first layer, the two regions and the two transistors being isolated from one another by the trench.

This provides a convenient means to electrically isolate the two transistors. This is of particular advantage where the two transistors are configured to operate at different voltages and/or different amperage. In the application of the device described in FIG. 1, it provides means to separate the power transistor 2 (typically operating at a high voltage) from the controller circuitry 3 (typically operating at a much lower voltage) whilst having them both integrated on the same wafer.

The first layer may be grown on the semiconductor material of the first type using epitaxy. Alternatively, though less preferred it could be formed by thermal deposition.

Favourably the first layer comprises polysilicon.

The trench may be formed using an etching process, e.g. deep reactive ion etching (DRIE).

The trench may introduce weakness in the wafer. Further contaminants may become trapped in the trench reducing the breakdown voltage of the trench. To ameliorate this the method may comprise filling the trench (e.g. such that it is substantially completely filled) with a electrically insulative material which may be a non-semiconductor, material.

The electrically insulative material may comprise silicon dioxide herein also referred to as silicon oxide, and may be formed using Tetraethyl orthosilicate (TEOS). TEOS provides a conformative coating that can penetrate deep into the wafer enabling the base of the trench to be filled. A possible alternative to TEOS includes boroophosphosilicate glass BPSG.

The electrically insulative material may be deposited on the surface of the semiconductor material in addition to filling the trench. The surface layer can be used to provide a barrier layer in which windows can be formed to define regions for patterning a subsequently deposited layer, e.g. polysilicon, in order to provide, for example, emitter and collector regions and/or contacts for one or more of the transistors.

The thickness of the electrically insulative material is favourably grown to be least half the width of the trench in order to fill the trench (as it will grow on both sides of the trench.

The trench may have a maximum width of about 5 micrometres, favourably a maximum width of about 1 micrometer.

The method may comprise forming a thermal oxide layer on the walls of the trench. This has the effect of healing crystal damage to the semiconductor (typically silicon) that may have resulted from etching to form the trench. Growing the oxide layer may be achieved by heating the semiconductor with oxygen. Additionally HCl may be added to the process to improve the quality of the silicon-oxide boundary and further reduce unwanted electrical effects.

The thermal oxide layer is typically grown before the trench is filled with the non-semiconductor, electrically insulative material.

The method may comprise providing a conductive layer (e.g. in the form of one or more conductive tracks) on the first layer that extends over the trench to provide an electrical connection between the two transistors on the opposite sides of the trench. The conductive layer may be, for example a metallic layer, though it could optionally be a polysilicon layer that is doped to a level of 1e19cm-2 or above.

A first of the two regions of the first layer may provide a base region for a first of the two transistors. A second of the two regions of the first layer may provide a base region for a second transistor of the two transistors. The two transistors may be configured as a Darlington pair.

One of the two regions may provide a substrate holding multiple transistors. The multiple transistors in the same region may form part of controller circuitry for controlling the bipolar transistor device.

In one embodiment the method may comprise forming a second trench that extends through the first layer so as to create at least three regions of first layer that are isolated from one another; a first of the three regions of the first layer providing a base region for a first transistor, a second of the two regions of the first layer providing a base region for a second transistor; and a third of the three regions providing a well holding multiple electronic devices that provide, at least in part, controller circuitry for controlling one or both of the first and second transistors.

Referring to FIG. 2B, improved transistor qualities are obtained by minimising the lateral separation between the p+ regions 103 104 that provide the of the collector and emitter. A problem with using polysilicon is that when etched there is usually significantly lateral etching, i.e. etching occurs laterally away from the opening in mask. This means that the minimum spacing between two separate pieces of polysilicon is limited to the minimum feature size of the lithography process used, plus twice the additional lateral etch distance of the polysilicon. As polysilicon regions are usually formed so as to extend over the barrier layer, this means that the barrier layer needs to be wider in order to accommodate both overlapping regions of the contacts and to provide a gap between them. As a result this leads to a wider spacing between the collector and emitter regions.

According to another aspect of the invention there is provided a method of forming a lateral transistor device, the method comprising:

providing a non-electrically conductive (e.g. silicon oxide) layer on a semiconductor substrate;

using a first mask in a first mask and etch process to provide two windows in the non-electrically conductive layer through which the semiconductor substrate is exposed; the two windows separated by a divider region of the non-electrically conductive layer;

depositing a conformal polysilicon layer over the non-electrically conductive layer and windows such that the polysilcon layer contacts the substrate through the windows;

using a second mask in a second mask and etch process to selectively remove the portion of polysilicon layer lying over the divider region to leave two isolated regions of polysilicon, each isolated region of polysilicon in contact with the substrate to provides respective anode regions of the lateral transistor; and

wherein the divider region feature size of the second mask used to selective remove the polysilicon layer lying over the divider region is substantially the same or larger than the feature size of the first mask used to define the divider region.

The invention lies, in part, in the realisation that the thickness of the conformal polysilicon layer will be greater around at the edges of the windows immediately adjacent the divider portion compared with its thickness across the rest of the window and the divider region. By controlling the etching time so that it does not exceed the time required to remove all of the thicker region of the polysilicon around the edges of the window it is possible to retain a portion of the thicker polysilicon layer such that the polysilicon layer extends right up to the edges of the divider portion. This allows for a narrow spacing between the polysilicon regions and thus a reduced separation between the collector and emitter.

### BRIEF DESCRIPTION OF THE SEVERAL VIEWS OF THE DRAWINGS

The invention will now be described by way of example with reference to the following figures in which:

FIG. 1 is a schematic of bipolar junction transistor device;

FIG. 2A is a schematic of a circuit comprising a PNP bipolar junction transistor and a reversed biased zener diode, which implements an inverter logic gate (NOT gate);

FIG. 2B is a schematic of a cross section side views of a semiconductor layer structure to provide a lateral PNP transistor and zener diode.

FIG. 3 is a schematic layer structure of a transistor device;

FIG. 4 is a schematic of a layer structure to form one of the power transistors showing a variant trench arrangement of FIG. 3;

FIGS. 5A -5G illustrate process steps of a method to form lateral transistors;

FIGS. 6A-6G illustrate process steps of a variant method to form lateral transistors;

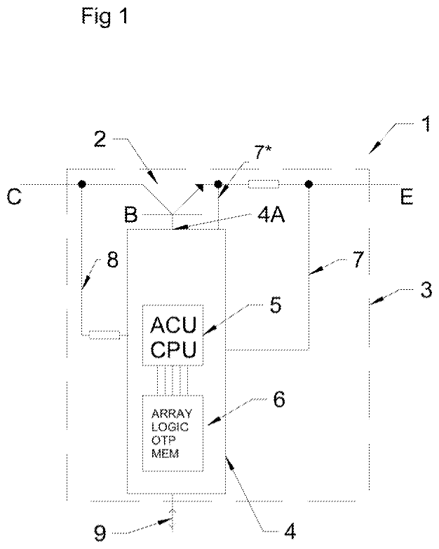

### DETAILED DESCRIPTION

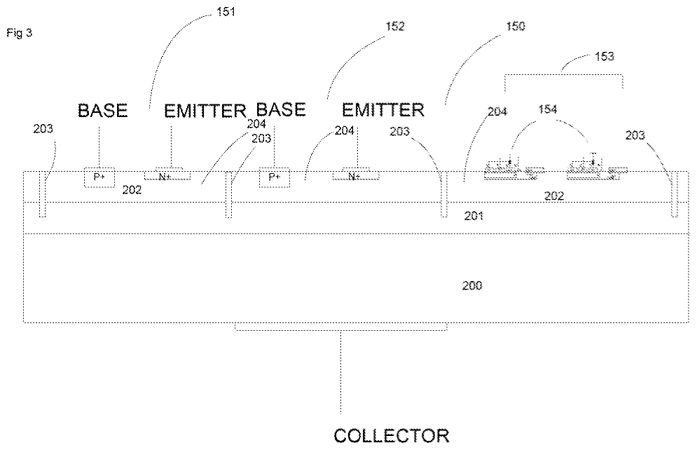

FIG. 3 is a simplified schematic of a transistor device 150. The transistor device 150 comprises two vertical NPN bipolar junction transistors 151, 152 configured as a Darlington pair. In variant embodiments the device 150 may comprise only a single vertical bipolar junction transistor or more than two vertical bipolar junction transistors that share a common collector.

The transistor device 150 further comprises controller circuitry 153 used to control the Darlington pair. The controller circuitry 153 includes lateral PNP transistor devices 154. The vertical transistors 151, 152 and electronic components of the controller circuitry 153 including the lateral transistor devices 154 are integrated electronic components formed on a wafer of semiconductor material.

In the present embodiment the vertical transistors 151, 152 are power transistors, e.g. can operate with collector currents above 1 amp. The controller circuitry 153 has a lower maximum operating voltage and amperage than the vertical transistors 151, 152.

When the transistor device 150 is connected into an external circuit, the vertical power transistors 151, 152, under control from the controller circuitry 153, are configured to regulate power through the external circuit.

To manufacture the device 150 a monocrystalline N type layer 201 is deposited on an N type substrate 200. A monocystalline P type layer 202 is deposited on the N type layer 201. Both the N type layer 201 and P type layer 202 can be grown using an epitaxy process. The thickness of the two layers 201 202 are selected based on the intended maximum operational voltage of the device 150, and the doping concentrations of the N type substrate 200, N type layer 201 and P type layer 202. To achieve an operational voltage of >600V (i.e. a breakdown voltage >600V) a thirty to forty five micrometer N type layer 201 and a 7 to 17 micrometer P type layer 202 is considered suitable. Where a highly doped (less than one ohm, favourably milliohm) N substrate 200 is used, a thicknesses of 35 microns for the N layer 201 and 10 microns for the P layer 202 is considered suitable.

Following deposition of the N type layer 201 and P type layer 202, trenches 203 are formed by etching, e.g. by a deep reactive ion etching (DRIE) process such as the Bosch process, into the top surface of the wafer. The trenches 203 are formed with a depth sufficient to extend entirely through the P layer 202 and into the N layer 201. This ensures the trench 203 extends through the laterally extending PN junction between the N layer 201 and P layer 202. The trenches 203 act to subdivide the P layer 202 into a plurality of P regions 204 each electrically isolated from one another by the trenches 203. The P regions 204 provide respective base regions for the first and second power transistors 151, 152 of the Darlington pair. A separate region 204 provides a substrate for the electronic components, including lateral transistors 154 of the integrated controller circuitry 153.

It is favourable that the width of the etched trench 203 is no more than about 5 microns. Favourably the width of the etched trench is no more than around 1 micron. This is because an increasing width of trench leads to an increased voltage at the base of the trench 203, i.e. a voltage closer to that of the collector C of the power transistors 101, 102, the collector terminal being connected to the substrate 200). This is because the PN junction of the base-collector forms a depletion region that holds off the high voltage at the collector. If the trench 203 is too wide, the centre of the bottom of the trench 203 will be sufficiently far away from the depletion region allowing the voltage to rise up from the collector to the base of the trench. The results in a localised high voltage spot.

Keeping the voltage at the base of the trench low is preferred as with higher voltages there is more likelihood of a breakdown about the walls of trench 203, which in effect are an extension of the top surface of the wafer. Breakdown is undesirable as the top side of the wafer is connected to the emitter and base of the transistors 151, 152 and so a breakdown from bottom to top of the wafer will result in a breakdown through the transistors 151, 152 and their destruction.

The voltage between the collector C and emitters E (Vce) of the transistors 151 152 of the Darlington pair formed using this structure can be improved by diffusing N dopant to the side and bottom of the trenches 203 which increases the effective surface area of the transistor collector/base interface.

The trench 203 may be filled with an electrical insulator material such as, for example, silicon oxide using Tetraethyl orthosilicate (TEOS), for example, as part of a subsequent oxide creation step using a method such as described in Trench Filling Characteristics Of Low Stress TEOS/Ozone Oxide Deposited By PECVD and SACVD; Microsystem Technologies 10 (2004) 97-102. This allows the trench 203 to be bridged by conductor layers for providing connective tracks that can be deposited later in the manufacturing process.

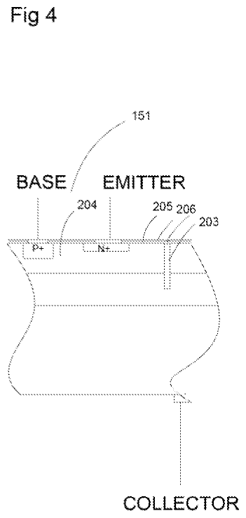

In a variation, illustrated in FIG. 4, the trench 203 may remain unfilled and a bridging layer 205 formed that extends laterally across the trench 203. The bridging layer 205 may be provided by a dielectric layer, e.g. of Borophosphosilicate and/or phosphosilicate glass, deposited over the wafer, e.g. as a precursor to the deposition of an electrically conducting (e.g. metal) layer 206 thereover for providing connective tracks.

The trench 203 may be used in a structure that omits the N layer 201 such that the P layer 202 sits directly on the N substrate 200. In such an example the trench 203 would extend into the substrate 200 and thus through the lateral PN junction formed between the substrate 200 and p layer 202.

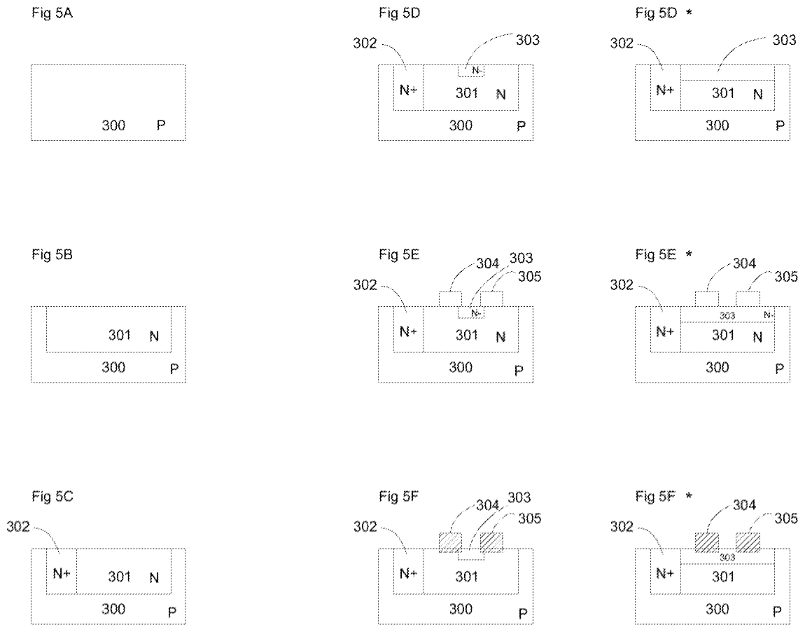

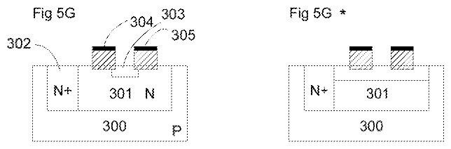

FIGS. 5A-5G illustrate a processing method suitable to form the lateral transistors devices 154 of the controller circuitry 153 of FIG. 3.

With reference FIG. 5A a P type region 300 is provided. In this example the P type region 300 corresponds to the P type epitaxial layer 202 on the substrate 200 of FIG. 3. However, where the method is used to manufacture devices other than that of FIG. 3, the P type region 300 could instead be provided through a preformed wafer or by doping a wafer.

Moving to FIG. 5B, a first implant and diffusion process is used with a first mask to form a N region 301 in the P type region 300. The net concentration of N dopant in the N region 301 is favourably around 1e17/cm3. Referring to FIG. 5B, using a second mask a further implant and diffusion process is used to form a heavily doped N+ region 302 which is contiguous with the N region 301. The net doping concentration of the N+ region 302 may be, for example, of a magnitude or about 1e18/cm3 or 1e19/cm3.

In a variation to the method, the heavily doped N+ region 302 may be formed first and the N region 301 then formed by implanting N dopant into the P type region and preferably the N+ region 302 at the same time to ensure the two regions are contiguous. Following implantation, a diffusion step is carried out to grow the region downward into the p type region 300.

With reference FIG. 5D, a relatively weakly doped N− region 303 is formed at the surface of the wafer by counter doping the relatively highly doped N region 301 with P dopant. An example of a preferred net concentration of n dopant in the N− region (i.e. difference between N dopant concentration and P type dopant concentration) is about 5e15/cm3.

Moving to FIG. 5E, a polysilicon layer is deposited on the surface of the wafer on either side of the N− region 303. The polysilicon layer is then implanted with P dopant in order to form the further P+ regions 304, 305 (FIG. 5F) that provides the collector and emitter regions of the lateral transistor. The P dopant is allowed to travel into the N− region 303 in order to ensure a PN junction is formed between the n− region 303 and each p region 304 305.

Implantation of P dopant is followed by a short anneal, e.g. 10 seconds, to repair the crystal structure of the polysilicon (and silicon wafer) whilst minimising if not avoiding diffusion of P dopant in the polysilcon, and more importantly diffusion of N dopant from the N regions 301 to the N− region 302 which would increase the net concentration of N dopant within the lightly doped region 303.

Thereafter, as is conventional, a metal layer is put down on the wafer over the polysilicon to provide the connectors for the emitter and collector (FIG. 5G).

The steps used to form the N+ regions 302 that provide the base contact region of the lateral transistors 104 can be used to simultaneously make the N+ regions that provide the emitter regions of the vertical NPN transistors 151, 152.

Similarly the polysilicon layer can also be used to define the base contacts 101B of the vertical transistors 151, 152.

The aforementioned method uses a mask to form the relatively weakly doped N− region 303 such that it is surrounded by the N region 301 as shown in FIGS. 5D-5G. However because of the amount of P type dopant infused is small compared with the difference in dopant concentration between the N+ region 302 and N region 301, it is possible to dispense with the mask and infuse across the whole of the wafer surface such as to form an N− region 303 that extends laterally across the whole of the N region 301 as illustrated in the variant method steps of FIGS. 5D*-5G*, without significant detriment to the N+region 302.

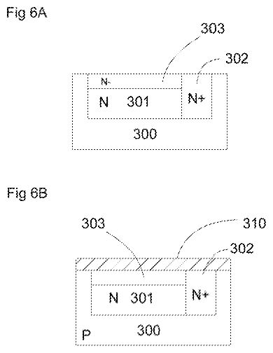

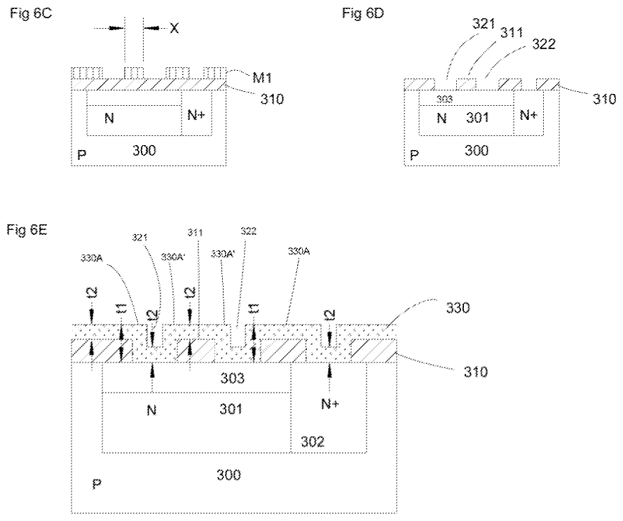

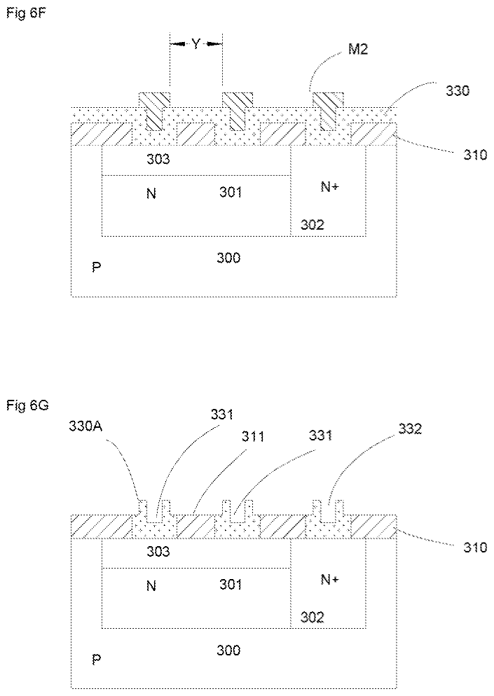

Improved performance of the lateral transistors 154 and greater transistor density within the controller circuitry 153 is obtained by minimising the spacing between the emitter and collector regions of the lateral transistors 154. With reference to FIGS. 6A-6F. The following describes a method to provide a reduced spacing between the emitter and collector regions of the lateral transistors 154.

With reference to FIG. 6A there is provided the P type region 300 with N region 301, N+ region 302 and N− region 303 formed using the afore described method.

With reference FIG. 6B a silicon oxide layer 310 is deposited over (e.g. substantially the entire) wafer including over the N+ region 302 and N− region 303.

Advantageously, the oxide layer 310 can be the same layer used to fill the trench 302 of the device of FIG. 3. This reduces the number of processing steps required to manufacture the device 150.

Turning to FIGS. 6C and 6D, using a first resist mask M1 and etch process, windows 321, 322 are formed in the oxide layer 310 to expose portions of the N− region 303. The two windows 321 322 are isolated from one another by a dividing portion 311 of the oxide layer 310 left behind following the etch process. Preferably the width of the dividing portion 311 that defines the closest spacing between the windows 321 322 is defined by to the smallest feature size X that can be formed with the mask M1 used to etch the oxide layer 310.

Referring to FIG. 6E, subsequent to the formation of the windows 321 322, a layer of polysilicon 330 is deposited over the wafer. The polysilicon may be deposited over substantially the entire wafer avoiding the need for an additional mask process. The polysilicon layer 330 is then implanted with a P dopant. The P dopant is allowed to travel into the N− region 303 in order to ensure a PN junction is formed between the n− region 303 and each p region 304 305.

Polysilicon deposits conformally over the contoured surface of the wafer. As such the thickness t1 of the polysilicon layer 330 at regions 330A lying at the edges of the windows 321, 322, including regions 330A′ immediately adjacent the dividing portion 311, are thicker (judged about an axis extending normal to the upper plane of the wafer) than the thickness t2 of the polysilicon layer 330 across either the centre of the windows 321, 322 or directly on the top of the oxide layer 310 including directly on top of the dividing portion 311. The increased thickness of regions 330A 330A′ provides means for compensating for the increased lateral etching that occurs when etching polysilicon compared with etching the oxide layer.

Referring to FIGS. 6F and 6G a further resist mask M2 and etching process is used to selectively remove portions of the polysilicon layer 330 including that lying directing on top of the divider portion 311 so as to form separate polysilicon regions 331 that provide respective collector and emitter regions of the lateral transistor. The polysilicon regions conform to the shape of windows 321, 322 on top of the n-region 303. The polysilicon regions 331 332 are separated by the dividing portion 311.

The feature size Y (see FIG. 6F) used in the further mask M2 to remove the portion of the polysilicon layer 330 directly on top of the dividing portion 311 is favourably substantially the same as the feature size X of the mask M1 used to create the dividing portion 311 from the oxide layer 310. Again, Y is favourably the smallest mask feature size that can be formed with the mask chosen. Notwithstanding, because of increased lateral etching that occurs when etching the polysilicon layer 330 compared with the silicon oxide layer 310, portions of the polysilicon regions 330A′ will be etched away.

The timing of the polysilicon etch is selected to substantially completely remove the portion of the polysilicon layer 330 lying on top of the dividing portion 311 whilst only removing a portion of the comparatively thicker regions 330A′ as a result of lateral etching. The minimum etch time is sufficient to remove thickness t1 of polysilicon layer 330. The maximum etch time is shorter than that which will etch thickness t2 of polysilicon layer 330. Favourably the etch time is as close as possible to the minimum etch time.

Following the polysilicon etch, regions 330A′ in contact with the dividing regions remain. This means that the shape of the polysilicon regions 331 conform to the shape of the respective windows 321, 322 in which they lie. It also means that the spacing between the polysilicon regions 331 equate to the size of the dividing portion 311.

Depending on the dimension (width) of the comparatively thick portion 330A′from the window edge towards the window centre, the size of divider region feature Y of mask M2 used to etch the polysilicon layer 330 may be larger than the features size X of mask M1 used to define the divider region from the oxide layer. The limitation being that feature isn't so wide as to result in removal of the relatively thin central portions of the polysilicon regions 331, i.e. those with thickness t1.

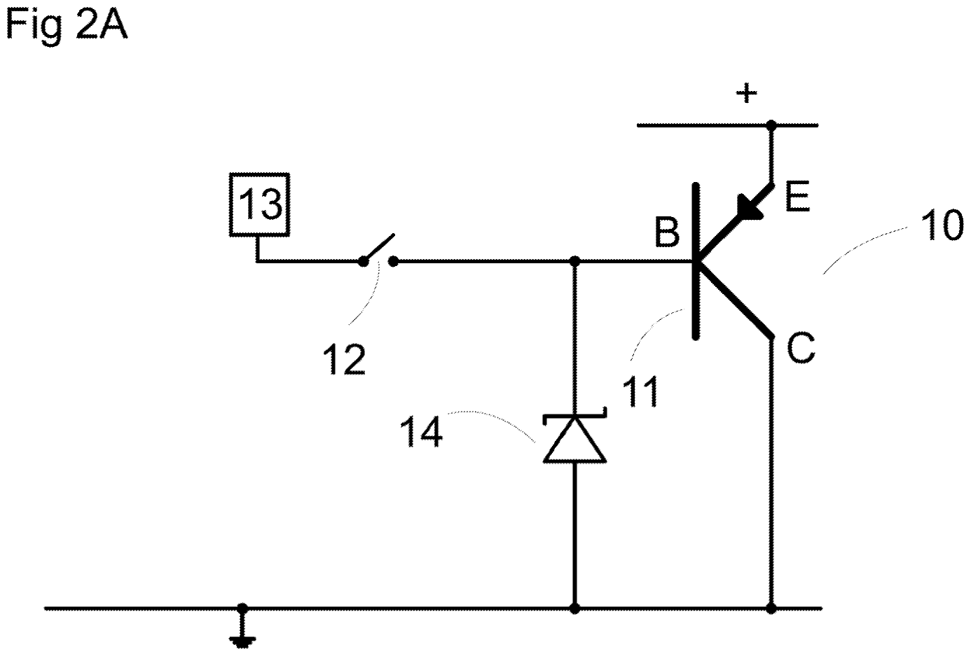

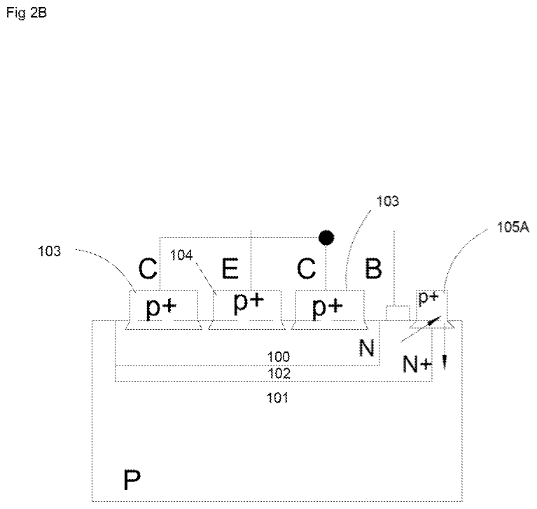

A further polysilicon region 332 is also made at the same time to provide a base contact for the transistor. This process can similarly be used to form, simultaneously, a further polysilicon region to form one half of the diode of FIG. 2B, i.e. by arranging it to span across the N+ region 302 and N region 300.

Following etching of the polysilicon layer 310 a metal layer to provide contacts may be provided over the polysilicon as well as a further oxide layer to provide protective coating.

The above described methods can be combined with a number of the masks being used to form features of both the vertical and lateral transistors. An example method is described below for manufacturing a vertical and lateral transistor such as that of FIG. 3, that operate at different maximum voltages or maximum amperages, both integrated on the same piece of semiconductor. The method comprises:

Provide a N-type substrate (200 (optionally with 201) with P-layer(202);

with a first mask, implant and diffuse N dopant to form N-type regions in the P-type layer; the N-type regions providing the emitter region of the vertical transistor 151, 152 and base region 301 of the lateral transistors 154;

with a second mask, implant and diffuse further N dopant to form N+base contact regions of lateral transistors 154. This second implant and diffuse process could optionally be used to form the emitter region of the vertical transistor instead of the first mask;

implant (typically without a mask) p-type dopant across the wafer to form the n− region 303 of the lateral transistors;

using a third mask etch the trenches 203;

deposit an oxide layer 330 over the wafer such that the oxide fills the trench 302;

with a fourth mask, etch the oxide layer 310 to form windows for the base contact for the vertical transistor, and collector and emitter regions of the lateral transistors 154;

with a fifth mask, deposit polysilicon 330 and dope with P dopant; etch to form base contact for vertical transistor, and collector and emitter regions of lateral transistors 154;

with a sixth mask, deposit a pre-metal oxide layer and etch to form metal contact windows;

with a seventh mask, deposit metal and etch to form traces.

In a less preferred variant of the afore described methods, the N− regions 303 may be omitted.

The inventions have been described in relation to a power transistor device. Nevertheless the afore described methods can equally be used to manufacture transistors used in other applications, e.g. for the formation of electronic memory circuitry (e.g. flip-flop) microcontroller and motor drives and motor controllers. The above described methods are described in relation to silicon semiconductors, it will be appreciated, depending on the requirements of application of the device, the method could also be used to create transistors from semiconductor materials other than silicon.

In the above examples the power transistors 101, 102 are vertical NPN bipolar transistors and the lateral transistors 104 are lateral PNP transistor devices. It will be appreciated that the method described above could be used to manufacture a device with vertical PNP transistors and lateral NPN transistor devices by swapping the order of the N and P layers.

The terms N−, N, N+, N++ and similarly P P+ are used within the specification as relative terms. But the following is a proximate guide of preferred doping concentrations: N−=1e15-1e16, N=1e17-1e18, N+=7e18-5e19, N++>5e19.

The illustrations of embodiments described herein are intended to provide a general understanding of the structure of various embodiments, and they are not intended to serve as a complete description of all the elements and features of apparatus and systems that might make use of the structures described herein. Many other embodiments will be apparent to those of skill in the art upon reviewing the above description. Other embodiments may be utilized and derived therefrom, such that structural and logical substitutions and changes may be made without departing from the scope of this disclosure. Figures are also merely representational and may not be drawn to scale. Certain proportions thereof may be exaggerated, while others may be minimized.

Accordingly, the specification and drawings are to be regarded in an illustrative rather than a restrictive sense. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description. Therefore, it is intended that the disclosure not be limited to the particular embodiment(s) disclosed as the best mode contemplated for carrying out this invention, but that the invention will include all embodiments falling within the scope of the appended claims.

What is claimed is:

1. A method of manufacturing a semiconductor bipolar transistor device, the semiconductor device comprising two transistors the method comprising;
providing a semiconductor material of a first type having provided on it a first layer of a semiconductor material of a second type;
forming two transistors on and/or in the first layer;
forming a trench that extends through the first layer so as to create two regions of the first layer, the two regions and the two transistors being isolated from one another by the trench.

2. A method according to claim 1 wherein the first layer is grown on the semiconductor material of the first type using epitaxy.

3. A method according to claim 1 or 2 wherein the first layer comprises polysilicon.

4. A method according to any claim 1-3 comprising filling the trench with an electrically insulative material.

5. A method according to claim 4 wherein the electrically insulative material is deposited on the surface of the semiconductor material in addition to filling the trench.

6. A method according to claim 5 wherein the thickness of the electrically insulative material is at least half the width of the trench.

7. A method according to any previous claim wherein the trench has a maximum width of about 5 micro metres.

8. A method according to any previous claim comprising growing a thermal oxide layer in the trench.

9. A method according to claim 8 wherein the thermal oxide layer is grown before the trench is filled with the electrically insulative material.

10. A method according to any previous claim comprising providing a conductive layer on the first layer that extends over the trench to connect between the two transistors on the opposite sides of the trench.

11. A method according to any previous claim wherein a first of the two regions of the first layer provides a base region for a first of the two transistors.

12. A method according to claim 11 wherein a second of the two regions of the first layer provides a base region for a second transistor of the two transistors.

13. A method according to claim 12 wherein the two transistors are configured as a Darlington pair.

14. A method according to any claim 1-11 wherein one of the two regions provides a substrate holding multiple transistors.

15. A method according to claim 14 wherein the transistors in the different regions of the first layer are configured to operate at different voltages.

16. A method according to claim 14 or 15 wherein the multiple transistors form part of controller circuitry for controlling the bipolar transistor device.

17. A method according to any claim 1-10 comprising forming a second trench that extends through the first layer so as to create at least three regions of first layer that are isolated from one another; a first of the three regions of the first layer providing a base region for a first transistor, a second of the two regions of the first layer providing a base region for a second transistor; and a third of the three regions providing a well holding multiple electronic devices that provide, at least in part, controller circuitry for controlling one or both of the first and second transistors.

18. A method of forming a lateral transistor device, the method comprising:
providing a non-electrically conductive layer on a semiconductor substrate;
using a first mask in a first mask and etch process to provide two windows in the non-electrically conductive layer through which the semiconductor substrate is exposed; the two windows separated by a divider region of the non-electrically conductive layer;
depositing a conformal polysilicon layer over the non-electrically conductive layer and windows such that the polysilicon layer contacts the substrate through the windows;
using a second mask in a second mask and etch process to selectively remove the portion of polysilicon layer lying over the divider region to leave two isolated regions of polysilicon, each isolated region of polysilicon in contact with the substrate to provides respective emitter and collector regions of the lateral transistor; and
wherein a divider region feature size of the second mask used to selective remove the polysilicon layer lying over the divider region is substantially the same or larger than a divider region feature size of the first mask used to define the divider region.

19. A method according to claim 18 wherein the non-electrically conductive layer comprises silicon dioxide.

20. A method of manufacturing a transistor device comprising an integrated circuit comprises a lateral transistor and vertical transistor, the method comprising:
providing a wafer comprising a semiconductor substrate of a first type having a semiconductor layer of a second type thereon;
with a first mask, implanting and diffusing dopant of the first type to form a first and second regions of the first type in the semiconductor layer to provide respectively: an emitter region of the vertical transistor and a base region of a lateral transistor;
with a second mask, implanting and diffusing further dopant of the first type into the first and second regions of the first type to convert at least a part of the first region of the first type to a first relatively highly doped region of the first type, and part of the second region of the first type to a second relatively highly doped region of the first type to provide a base contact region of the lateral transistor;
implanting dopant of the second type across the wafer to convert an exposed surface region of the second region of the first type to a relatively low doped region of the first type;
using a third mask, etching the surface of the wafer to form a trench that extends through the semiconductor layer of the second type to divide the semiconductor layer of the second type into multiple electrically isolated regions; a first of the regions of the semiconductor layer providing a base region of the vertical transistor, and a second of the regions of the semiconductor layer providing a substrate layer for the lateral transistor;
depositing an oxide layer over the wafer such that the oxide fills the trench;
with a fourth mask, etching the oxide layer to form separated windows therein; one of the windows exposing a portion of the first region of the semiconductor layer and two other windows exposing regions of the relatively low doped region of the first type;
with a fifth mask, depositing polysilicon over the wafer and doping the deposited polysilicon with dopant of the second type; etching the deposited polysilicon to form a base contact for vertical transistor and collector and emitter regions of the lateral transistor;

21. A method according to claim 20 wherein the method further comprises:
depositing a pre-metal oxide layer over the wafer, and with a sixth mask etching to form contact windows for metal deposition;
depositing a metal layer over the wafer and with a seventh mask etching the metal layer to form traces.

22. A method according to claim 20 or 21 wherein implanting dopant of the second type across the wafer to form the n− region of the lateral transistors comprising implanting dopant of the second type across substantially the whole surface.

23. A method of forming a lateral bipolar transistor device, the method comprising:
implanting a dopant of a first type into a semiconductor of a second type to form a relatively highly doped region of the first type within the semiconductor;
counterdoping a portion of the region of the first type with dopant of the second type to form a relatively lightly doped region of the first type within the relatively highly doped region of the first type, the relatively lightly doped region of the first type having a net concentration of dopant of the first type that is lower compared with the relatively highly doped region of the first type; the relatively highly doped region of the first type and relatively lightly doped region of the first type providing a base region of the transistor;
depositing a layer of silicon oxide onto the surface semiconductor at locations adjacent the relatively lightly doped region and implanting dopant of the second type into the silicon oxide layer to form regions of the second type immediately adjacent to, in direct contact with and physically isolated from one another by the relatively lightly doped region; the regions of the second type providing emitter and collector regions of the transistor.

24. A method according to claim 23 wherein the net concentration of dopant of the first type in the relatively lightly doped region is 5e15/cm3, and the net concentration of dopant of the first type in the relatively highly doped region is 1e17/cm3.

25. A method according to claim 23 or 24 comprising forming a relatively very heavily doped region of the first type in the semiconductor, and then implanting the semiconductor with the dopant of the first type to form the relatively highly doped region of the first type, the heavily doped region; a relatively very heavily doped region of the first type forming part of the base region of the transistor.

26. A method according to claim 25 wherein the relatively very heavily doped region of the first type has a net concentration of n type dopant of at least 1e18/cm3, favourably at least 1e19/cm3.
